(19) United States
(12) Patent Application Publication
(10) Pub. No.: US 2002/0182773 A1
(43) Pub. Date: Dec. 5, 2002

(54) Method for bonding inner leads of leadframe to substrate

(75) Inventors: Chun-Jen Su, Kaohsiung (TW); Chien-Hung Lai, Kaohsiung (TW); Chien-Tsun Lin, Kaohsiung (TW); Chao-Chia Chang, Kaohsiung (TW)

Correspondence Address: DOUGHERTY & TROXELL, 5205 LEESBURG PIKE, SUITE 1404, FALLS CHURCH, VA, 22041, US

(73) Assignee: Walsin Advanced Electronics LTD

(21) Appl. No.: 09/871,623

(22) Filed: Jun. 4, 2001

(51) Int. Cl. H01L 23/495; H01L 23/48; H01L 21/44; H01L 21/48; H01L 21/50

(52) U.S. Cl. 438/111; 257/666; 257/673; 257/678; 257/696; 438/118; 438/123

(57) ABSTRACT

A method for bonding inner leads of lead frame to substrate includes the steps of: (a) providing a substrate, the substrate having a plurality of connection pads formed on the electrical bonding surface of the substrate; (b) providing a lead frame with a dam tape adhered on of the inner leads of the lead frame; (c) thermally compressing the inner leads of lead frame onto the substrate, wherein a solder material is formed between the inner end and the corresponding connection pad of the substrate and the solder material is limited by the dam tape during inner lead bonding, so that there is stable electrical and mechanical connection between inner leads and the substrate.

### FIELD OF THE INVENTION

The present invention relates to a method for bonding inner leads of a lead frame to a substrate, more particularly to a method for bonding inner leads of a lead frame to a substrate, wherein a dam tape adhered to the lead frame to prevent solder material flow-out and to fix the inner leads of the lead frame.

### DESCRIPTION OF THE PRIOR ART

It is familiar to encapsulate a semiconductor chip and a lead frame with a package body against outer impact, which these lead strips of the lead frame extend outsides the package body for electrically connecting to PCB (printed circuit board), such as outer leads around the perimeter of the package body in QFP type (Quad Plat Package) or outer leads around bilateral side of the package body in SOP type (Small Outline Package).

One of common ways for making inner electrical connection between lead strips and a semiconductor chip is to engage wire-bonding technique, but such a process have to be completed one by one at a time by a wire-bonding machine until all wires are formed, resulting in poor efficiency of production. In order to reduce time of manufacturing, especially in a bonding process between lead strips and a semiconductor chip, U.S. Pat. No. 6,080,604 “SEMICONDUCTOR DEVICE HAVING TAB-LEADS AND A FABRICATION METHOD THEREOF” disclosed an inner lead bonding method for semiconductor device. By means of thermal compression, a plurality of inner lead tips bond to a semiconductor chip with a TAB tape. As shown in FIGS. 1 and 2, a semiconductor package 100 comprises a semiconductor chip 110 having an electrical bonding surface 111 and a plurality of bumps 112 formed thereon, a TAB (Tape Automated Bonding) tape 150 adhered on the electrical bonding surface 111 by a first thermal compression step, and a plurality of lead strips 130 of a lead frame. The TAB tape 150 is made by a polyimide film coating two-sided adhesive with TAB leads 140. The TAB tape 150 has an opening 151 less than the electrical bonding surface 111 of the semiconductor chip 110 for exposing the bumps 112. The inner ends of the TAB leads 140 bond to the bumps 112 by one time of second thermal compression, the outer ends of the TAB leads 140 bond to the lead strips 130 of the lead frame by one time of third thermal compression. Then follows a series process of molding, encapsulant injection, and mechanical cutting, a semiconductor package 100 as shown in FIG. 1 and FIG. 2 is obtained. Since TAB tape 150 with TAB leads 140 is flexible enough to reel, the TAB leads 140 are unable to provide a proper mechanical strength to fix the semiconductor chip 110 during encapsulant injection, resulting in displacement or incline of the semiconductor chip 110. Besides, it is a little troublesome because there are three thermal compression processes required in the manufacture of the semiconductor package 100.

### SUMMARY OF THE INVENTION

It is a primary object of the present invention to provide a method for bonding inner leads of lead frame to a substrate for avoiding the solder material flowing-out during thermal compression process. By means of thermal compression to directly bond the inner leads of lead frame to the connection pads of substrate, there are solder material between the lead strips and connection pads of substrate. In order to prevent solder material flowing-out, a dam tape is adhered to the lead strips near the perimeter of a substrate. So that the solder material limited by the dam tape offers stable mechanical strength and electrical connection between the lead strips and connection pads of substrate to obtain a fast and stable bonding.

It is a secondary object of the present invention to provide a semiconductor package with a dam tape. The inner leads of lead frame are directly bonded to a substrate by solder material and adhered a dam tape near the perimeter of the substrate for preventing solder material flowing-out for obtaining the efficacies of stable mechanical strength and electrical connection and molding flowbalance.

According to the method for bonding inner leads of lead frame to a substrate in the present invention, the processes are as described hereinafter:

(a) providing a substrate, the substrate having a plurality of connection pads formed on the electrical bonding surface of the substrate; (b) providing a lead frame with a dam tape adhered on of the inner leads of the lead frame; (c) thermally compressing the inner leads of lead frame onto the substrate, wherein a solder material is formed between the inner end and the corresponding connection pad of the substrate and the solder material is limited by the dam tape during inner lead bonding, so that there is stable electrical and mechanical connection between inner leads and the substrate.

### BRIEF DESCRIPTION OF THE DRAWINGS

FIG. 1 is a cross sectional view of a semiconductor package disclosed in U.S. Pat. No. 6,080,604 “semiconductor device having TAB leads and a fabrication method thereof”.

FIG. 2 is a top view of a semiconductor package disclosed in U.S. Pat. No. 6,080,604 “semiconductor device having TAB leads and a fabrication method thereof”.

FIG. 3 is a cross sectional view of a semiconductor package of one embodiment according to the present invention.

FIG. 4 is a partial view of a provided lead frame of one embodiment according to the present invention.

FIG. 5 is a cross sectional view of a provided lead frame bonding to substrate of one embodiment according to the present invention.

FIG. 6 is a bottom view of a provided substrate of a further embodiment according to the present invention.

FIG. 7 is a bottom view of a provided lead frame of a further embodiment according to the present invention.

FIG. 8 is a bottom view of the provided lead frame bonding to substrate of another embodiment according to the present invention.

FIG. 9 is a cross sectional view of a semiconductor package of another embodiment according to the present invention.

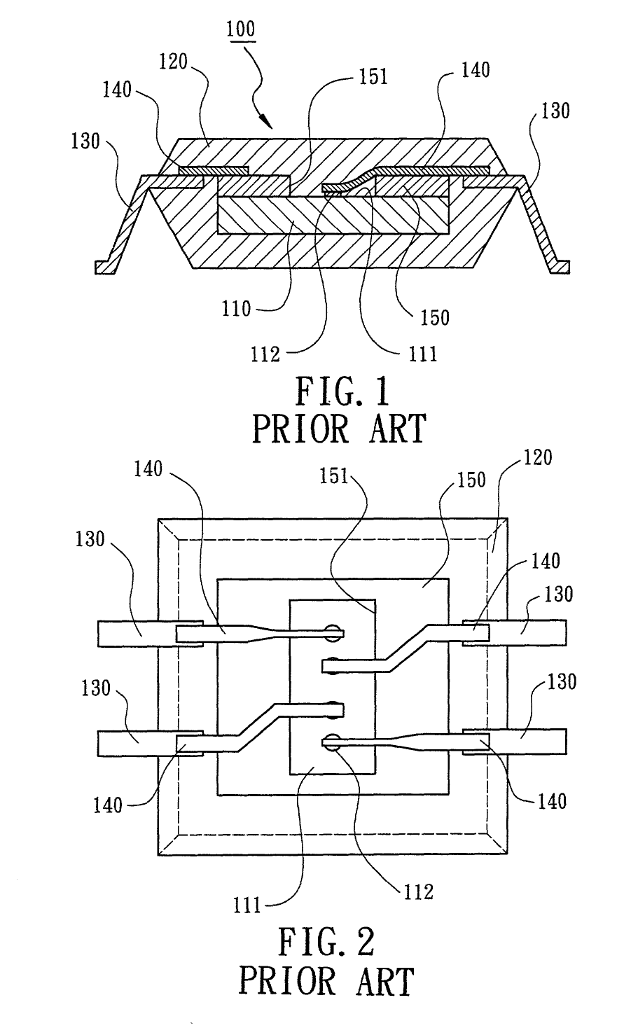

### DETAILED DESCRIPTION OF INVENTION

Referring to the attached drawings, the present invention is described by following embodiments.

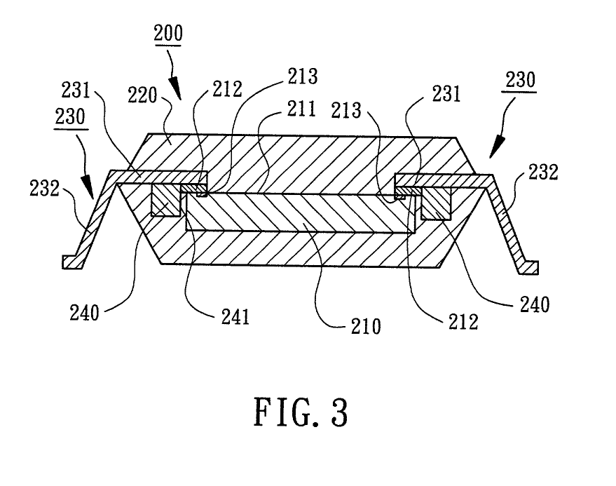

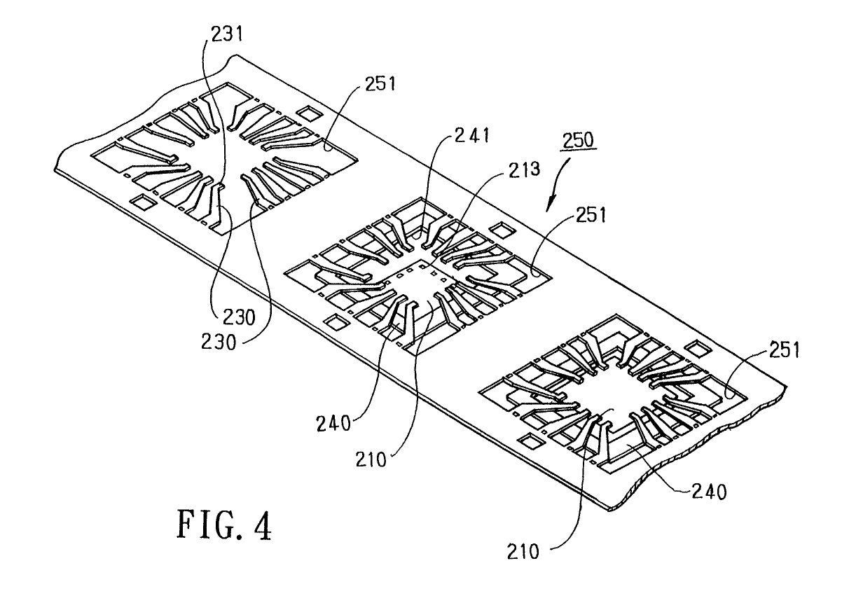

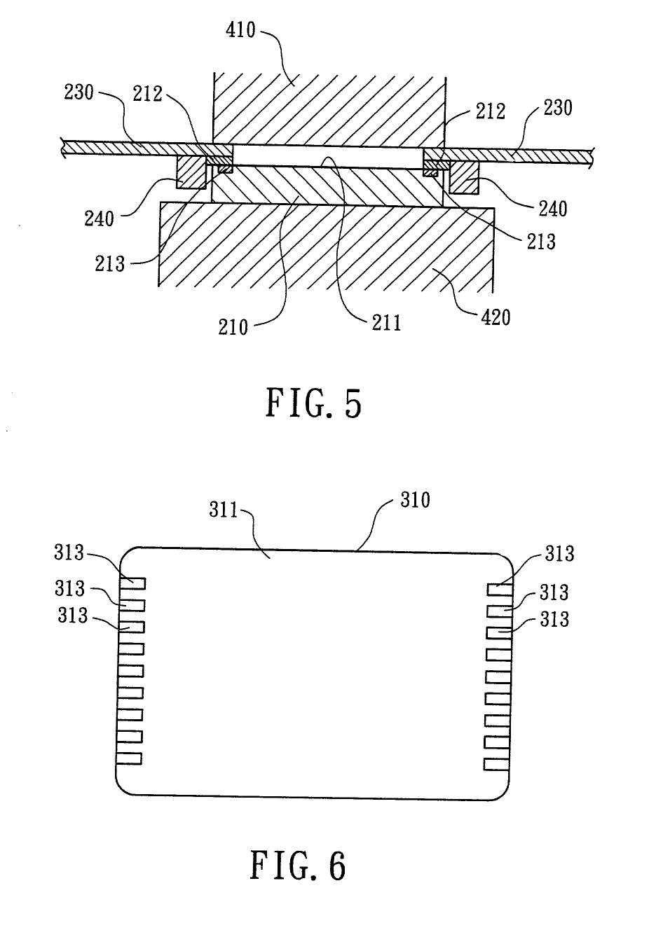

FIG. 3, FIG. 4, and FIG. 5 are illustrated about the first embodiment of the present invention. A method for bonding the inner leads of lead frame to substrate, as shown in FIG. 4, at first there is a lead frame 250 made by means of well-known stamping or etching method applying a metal plate of copper, iron, or alloy 42 (alloy 42 is composed of nickel 42% and iron 58%), in this embodiment a copper plate with better thermal conductivity is preferred. The lead frame 250 has a plurality of frame holes 251, and there is a plurality of lead fingers 230 in each frame hole 251. A plurality of inner ends of the lead fingers 230 are corresponding to the connection pads 213 of a substrate 210 and extend to form an inner lead 231. A window tape 240 is adhered around the inner leads 231 of lead strips 230 for that a plurality of lead strips is not easy to deviate and is on a same plane. Preferably, the window tape 240 is a polyimide tape with single-faced viscosity and has an opening 241 being a little bigger than the substrate 210 so as not to contact the substrate 210 (as shown in FIG. 3).

In this embodiment, the substrate 210 is one kind of semiconductor chip having a silicon substrate with connection pads 213 such as aluminum or copper pad, formed around the perimeter of the electrically bonding surface 211, by be imbedded a number of integrated circuit elements to constitute a micro-processor, memory chip or logic chip etc. In this embodiment, by means of electroplating, evaporation, wire-boning or by lithography tecknique, solder materials 212 are formed on the connection pads 213 of the substrate 210 as so called bump, like gold bump or lead-tin bump.

As shown in FIG. 5, while lead frame 250 is transported to a determined position, a surface of the lead strips 230 adhered with window tape 240 orients toward the substrate 210 being moving upward by pedestal 420, that is, the surface (so called lower surface) with a window tape 240 of lead strips 230 is facing the electrically bonding surface 211 of substrate 210. The inner leads 231 of lead strips 230 are corresponding to the connection pads 213 of substrate 210. The inner leads 231 of lead strips 230 are compressed downwards by a compression head 410 with the temperature of centigrade a few hundreds degrees. The solder materials 212 between the inner leads 231 of lead strips 230 and the corresponding connection pads 213 of substrate 210 melt by heat and pressure, so that a plurality of inner leads 231 of lead strips 230 are bonding to the corresponding connection pads 213 of substrate 210 by one thermal compression. Besides during thermal compression, the window tape 240 is adjacent to electrically bonding surface 211 of substrate 210 so that the solder material 212 is limited or blocked by window tape 240 to keep a proper amount. The solder material 212 provides a better bonding between inner lead 231 of lead strip 230 and corresponding connection pad 213, and is evenly formed between the inner leads 231 and the corresponding connection pads 213. Finally, as shown in FIG. 3 the semiconductor package 200 may be obtained after molding, curing and cutting.

Therefore, the method for bonding the inner leads of lead frame to substrate in the present invention has advantages below:

First, it can finish quickly bonding of the lead strips 230 of lead frame and substrate 210 by one thermal compression without solder material 212 flowing-out;

Second, the solder material 212 without flowing-out limited by window tape 240 provides a stable mechanical bonding strength between lead strips and substrate;

Third, the lead strips 230 under the limit of window tape 240 have an excellent coplanarity and are not easy to deviate during manufacturing process, so that there is no necessary to trim the dam bar after encapsulating; and

Forth, the window tape 240 located around the substrate 210 has an efficacy for rectifying the molding flow under a proper form.

According to the method mentioned above for bonding the inner leads of lead frame to substrate, as shown in FIG. 3, a semiconductor package 200 comprises a substrate 210, a plurality of lead strips 230, a plurality of solder materials 212, a window tape 240 and a package body 220. The substrate 210 is a semiconductor chip and has an electrically bonding surface 211 forming a plurality of connection pads 213. A plurality of leads strips 230 have inner leads 231 at the inner ends and outer leads outside the package body 220, wherein the inner leads 231 are corresponding to the connection pads 213 of substrate 210. A plurality of solder materials 212 are formed between inner leads 231 and connection pads 213 for electrically connecting and mechanically bonding the lead strips 230 to the substrate 210. A window tape 240 adhered to the lead strips 230 near the electrically bonding surface 211 of substrate 210 is used to fix the lead strips 230 and limit the solder material 212. A package body 220 is used to protect the substrate 210. Then, the semiconductor package 200 has efficacies for quickly inner electrical connection, stable mechanical bonding strength and a better molding flow.

In order to well understand the method for bonding inner leads of lead frame to substrate in the present invention, there is no limit for variety of substrate, the form of tape, etc, particularly a second embodiment is illustrated.

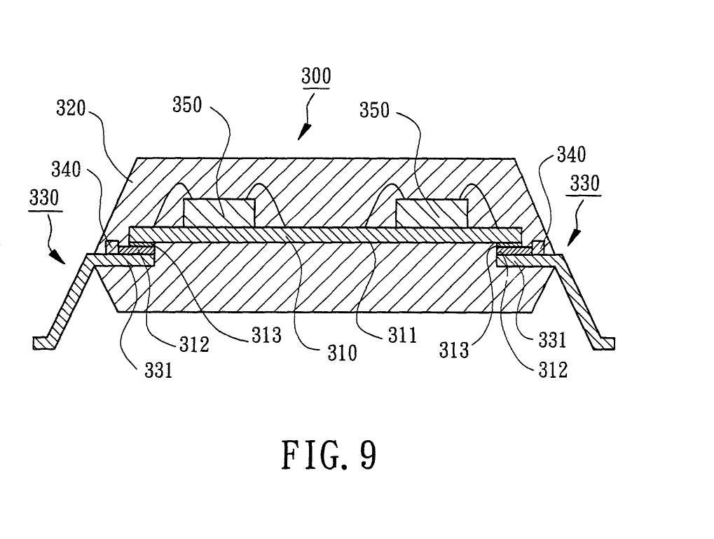

As shown in FIG. 6, first a substrate 310 is provided. The substrate 310 has an electrically bonding surface 311, such as a printed circuit board or ceramic circuit substrate. A plurality of connection pads 313 is formed on the electrically bonding surface 311 such as copper pads, etc. In this embodiment, the connection pads 313 formed as long finger shape are gold fingers for circuit substrate 310. The circuit substrate 310 may carry a plurality of chips 350 in advance (as shown in FIG. 9).

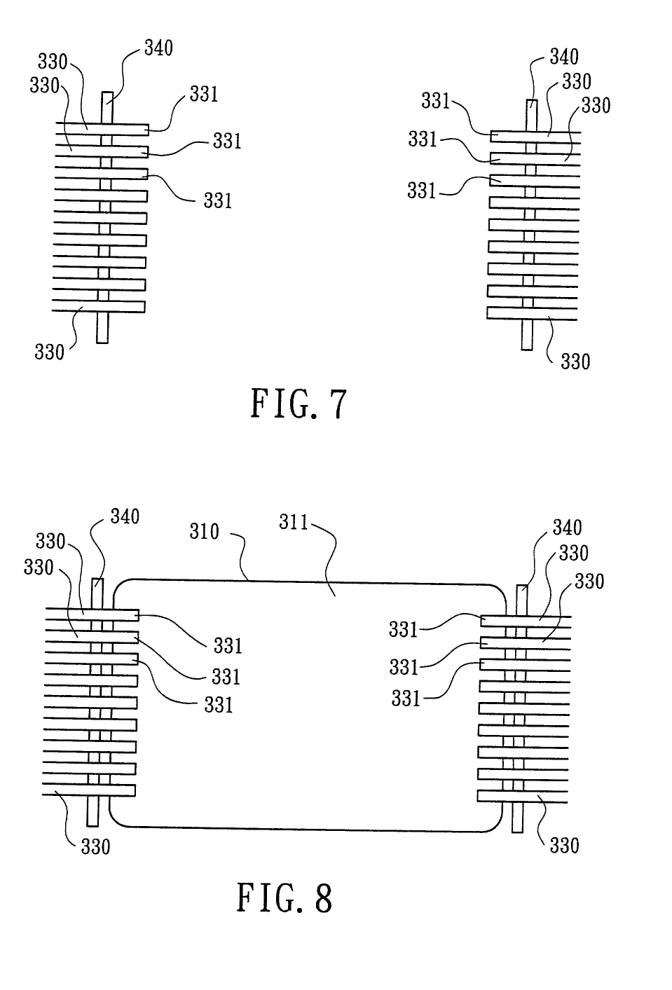

As shown in FIG. 7, then provide a lead frame with a plurality of lead strips 330. Wherein the inner leads 331 of a plurality of lead strips 330 are corresponding to the connection pads 313 of substrate 310. The solder materials 312 are electroplated to form on a surface of inner leads 331 such as conductive solder materials of nickel, palladium, lead-tin, gold, silver, etc. Besides, a strip type tam tape 340, such as polyimide, is adhered at the same side of lead strips 330 around the inner leads 331.

As shown in FIG. 8, the surfaces of lead strips 330 with dam tapes 340 face the substrate 310 for thermally compressing the inner leads 331 of lead strips 330 to the corresponding connection pads 313 of substrate 310. The solder materials 312 between the inner leads 331 of lead strips 330 and the corresponding connection pads 313 of substrate 310 melt and are limited by dam tapes 340 near the substrate 310, effectively keep solder materials 312 for bonding the inner leads 331 of lead strips 330 to the corresponding connection pads 313 of substrate 310. Finally after molding, curing and cutting, a semiconductor package 300 with multi-chip module may be obtained. At the same way according to the method for bonding lead strips of lead frame to the connection pads of substrate in the present invention, the semiconductor package 300 has efficacies of quickly inner electrical connection, stable mechanical bonding strength and better molding flow.

The above description of embodiments of this invention is intended to be illustrative and not limiting. Other embodiments of this invention will be obvious to those skilled in the art in view of the above disclosure.

What is claimed is:

1. A method for bonding inner leads of a lead frame to a substrate comprising the steps of:
providing at least a substrate, the substrate having an electrical bonding surface and a plurality of connection pads on the electrical bonding surface;
forming a lead frame adhered with at least a dam tape, the lead frame comprising a plurality of frame holes and a plurality of lead strips in each frame hole, the lead strips having inner leads corresponding to the connection pads of the substrate; and
thermally compressing the inner leads of the lead frame onto the connection pads of the substrate, wherein there is a solder material between the inner lead of the lead strip and the connection pad of the substrate and the dam tape being close to the electrical bonding surface of the substrate for blocking the solder material during inner lead bonding.

2. The method as claimed in claim 1, wherein said substrate is a semiconductor chip.

3. The method as claimed in claim 1, wherein said substrate is a circuit board

4. The method as claimed in claim 1, wherein said connection pad of the substrate has a shape like long finger.

5. The method as claimed in claim 1, wherein said dam tape is a window tape having an opening, the opening being a little bit bigger than the electrical bonding surface of the substrate.

6. The method as claimed in claim 1, wherein said dam tape is a strip type.

7. A semiconductor package comprising:
a package body;
a substrate having an electrical bonding surface and a plurality of connection pads on the electrical bonding surface;
a plurality of lead strips having inner leads inside the package body corresponding to the connection pads of the substrate;
a solder material between the inner lead and the connection pad of the substrate; and
at least a dam tape adhered to a surface of lead strips which orients toward the electrical bonding surface of the substrate, the dam tape being close to the electrical bonding surface of the substrate.

8. The semiconductor package as claimed in claim 7, wherein the substrate is a semiconductor chip.

9. The semiconductor package as claimed in claim 7, wherein said substrate is a circuit board.

10. The semiconductor package as claimed in claim 9, further comprising at least a semiconductor chip mounting on the circuit board.

11. The semiconductor package as claimed in claim 7, wherein said connection pad of the substrate has a shape like long finger.

12. The semiconductor package as claimed in claim 7, wherein the dam tape is a window tape having an opening, the opening being a little bit bigger than the electrical bonding surface of the substrate.

13. The semiconductor package as claimed in claim 7, wherein the dam tape is a strip type.
